(19) United States
(12) Patent Application Publication
(10) Pub. No.: US 2019/0393136 A1
(43) Pub. Date: Dec. 26, 2019

(54) POWER DEVICE FOR RECTIFIER

(71) Applicant: ACTRON TECHNOLOGY CORPORATION, Taoyuan City (TW)

(72) Inventor: Hsin-Chang Tsai, Taoyuan City (TW)

(73) Assignee: ACTRON TECHNOLOGY CORPORATION, Taoyuan City (TW)

(21) Appl. No.: 16/106,010

(22) Filed: Aug. 21, 2018

(30) Foreign Application Priority Data
Jun. 21, 2018 (TW) 107121274

(51) Int. Cl. H01L 23/492; H02M 7/00; H01L 23/31; H01L 23/528; H01L 23/29; H01L 25/16

(52) U.S. Cl. CPC H01L 23/4924; H02M 7/003; H01L 23/3114; H01L 29/78; H01L 23/293; H01L 23/3135; H01L 25/16; H01L 23/528

(57) ABSTRACT

A power device for a rectifier includes a first terminal and a second terminal for connecting an external circuit, and a circuit system located between the first terminal and the second terminal. The circuit system is electrically connected to the first terminal and the second terminal. The circuit system includes a pre-molded chip and a control device. The pre-molded chip includes a transistor and a first encapsulant for encapsulating the transistor, wherein the transistor has a first electrode, a second electrode, and a third electrode. The first terminal, the second terminal and the control device are respectively electrically connected to the first electrode, the second electrode and the third electrode of the transistor.

### CROSS-REFERENCE TO RELATED APPLICATION

This application claims the priority benefits of Taiwan application serial no. 107121274, filed on Jun. 21, 2018. The disclosure of which is hereby incorporated by reference herein in its entirety.

### BACKGROUND

### Technical Field

The disclosure is related to a power device and more particularly, to a power device for rectifier.

### Description of Related Art

In the existing vehicle transportation system, since the efficiency and life of an alternating current generator are much higher than that of a direct current generator, the current vehicle generators are all alternating current generators. In order to charge the alternating current generated by the alternating current generator into the battery, a rectifier diode is used to rectify the alternating current into direct current. As such, the electric power is supplied for various electrical devices in the vehicle system to operate continuously, and the vehicle can run without consuming the electric power stored in the battery, so as to keep abundant electric power in the battery for the next run. In general, 6 to 8 rectifier diodes are usually disposed on the electrode plates of an alternating current generator.

In the past, a PN junction diode was often used as a rectifier diode. However, the PN junction diode has a rather high forward voltage (V_{F}), which easily causes the problem of power conversion loss.

Therefore, a rectifier diode using a metal oxide semiconductor field effect transistor (MOSFET) to perform synchronous rectifying has been developed recently. Since the MOSFET has no built-in potential and has a low V_{F}, the loss is also low. However, driving the MOSFET needs additional control integrated circuit and so on to form a circuit system, the interconnection inner the circuit system is often complicated resulting in high parasitic effect, which affect the efficiency of the rectifier.

### SUMMARY

The disclosure provides a power device for rectifier having a circuit system with low parasitic effect and capable of further decreasing the V_{F} and thereby improving the efficiency of the rectifier.

A power device for rectifier of the disclosure includes a first terminal and a second terminal adapted for connecting an external circuit, and a circuit system located between the first terminal and the second terminal. The circuit system is electrically connected to the first terminal and the second terminal. The circuit system includes a pre-molded chip and a control device. The pre-molded chip includes a transistor and a first encapsulant, wherein the transistor has a first electrode, a second electrode and a third electrode, and the first encapsulant is adapted for encapsulating the transistor. The first terminal, the second terminal and the control device are respectively electrically connected to the first electrode, the second electrode and the third electrode of the transistor.

In an embodiment of the disclosure, the pre-molded chip further includes a patterned circuit layer electrically connected to at least one of the first electrode, the second electrode and the third electrode of the transistor, and the first encapsulant encapsulates the patterned circuit layer and exposes a part of the patterned circuit layer.

In an embodiment of the disclosure, the patterned circuit layer is electrically connected to the first electrode and the third electrode, and the first terminal and the control device are respectively electrically connected to the first electrode and the third electrode via the exposed part of the patterned circuit layer.

In an embodiment of the disclosure, the pre-molded chip encapsulated by the first encapsulant exposes the second electrode electrically connected to the second terminal.

In an embodiment of the disclosure, a material of the first terminal and a material of the second terminal comprise aluminum, copper or an alloy thereof.

In an embodiment of the disclosure, the transistor is a field effect transistor controlled by voltage or current.

In an embodiment of the disclosure, the transistor is a metal oxide semiconductor field effect transistor, an insulated gate bipolar transistor or a gallium nitride transistor.

In an embodiment of the disclosure, a material of the first encapsulant includes an epoxy resin, a silicone resin, a biphenyl resin, an unsaturated polyester or a ceramic material.

In an embodiment of the disclosure, the first terminal includes a base and a lead, a shape of a bottom surface of the base is a circle, a square or a hexagon and a shape of the second terminal is a circle, a square or a hexagon.

In an embodiment of the disclosure, the power device for rectifier may further include a conductive spacer, located between the pre-molded chip and the first terminal and adapted for electrically connecting the pre-molded chip and the first terminal.

In an embodiment of the disclosure, the conductive spacer and the first terminal are integrally formed.

In an embodiment of the disclosure, the power device for rectifier may further include a second encapsulant, located on the second terminal and adapted for covering the conductive spacer, the circuit system and a part of the first terminal.

In an embodiment of the disclosure, the power device for rectifier may further include a second encapsulant, located between the pre-molded chip and the first terminal and adapted for encapsulating the control device and the conductive spacer and exposing a part of the conductive spacer.

In an embodiment of the disclosure, the power device for rectifier may further include a bonding material, located between the second encapsulant and the first terminal.

In an embodiment of the disclosure, the power device for rectifier further includes a third encapsulant, located on the second terminal and adapted for covering the conductive spacer, the circuit system and a part of the first terminal.

In an embodiment of the disclosure, a material of the second encapsulant and a material of the third encapsulant comprise an epoxy resin, a silicone resin, a biphenyl resin, an unsaturated polyester or a ceramic material.

Another power device for rectifier of the disclosure includes a first terminal and a second terminal adapted for connecting an external circuit, and a pre-molded chip located between the first terminal and the second terminal. The pre-molded chip includes a transistor and a first encapsulant, wherein the transistor has a first electrode and a second electrode, and the first encapsulant is adapted for encapsulating the transistor, and wherein the first terminal and the second terminal are respectively electrically connected to the first electrode of the transistor and the second electrode of the transistor.

In another embodiment of the disclosure, the pre-molded chip further includes a patterned circuit layer electrically connected to the first electrode, wherein the first encapsulant encapsulates the patterned circuit layer and exposes a part of the patterned circuit layer, and the first terminal is electrically connected to the first electrode via the exposed part of the patterned circuit layer.

In another embodiment of the disclosure, the pre-molded chip exposes the second electrode electrically connected to the second terminal.

In another embodiment of the disclosure, a material of the first terminal and a material of the second terminal comprise aluminum, copper or an alloy thereof.

In another embodiment of the disclosure, a material of the first encapsulant includes an epoxy resin, a silicone resin, a biphenyl resin, an unsaturated polyester or a ceramic material.

A rectifier device of a vehicle generator of the disclosure includes the aforementioned power device for rectifier.

Based on the above, the circuit system in the power device for rectifier of the disclosure directly places the control device on the pre-molded chip, which is formed by encapsulating the transistor in the first encapsulant and the patterned circuit layer, and thereby completes the circuit connection. Since the circuit system in the power device for rectifier of the disclosure does not require additional wire bonding, a circuit system having a low parasitic effect is achieved. Also, due to the low resistance of the transistor then a reduced V_{F} is obtained, and thus the efficiency of the power device for rectifier is improved. In an embodiment where the control device is not required, the overall encapsulating reliability may be increased by first making the transistor into a pre-molded chip and then the pre-molded chip being electrically connected to the two terminals.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic cross-sectional view of a power device according to an embodiment of the disclosure.

FIG. 2 is a schematic top view of FIG. 1, and FIG. 1 is the cross-sectional view along the line section I-I in FIG. 2.

FIG. 3A is a schematic front view of a pre-molded chip according to the embodiment of the disclosure.

FIG. 3B is a schematic back view of the pre-molded chip of FIG. 3A.

FIG. 4 is a schematic cross-sectional view of a power device according to another embodiment of the disclosure.

FIG. 5 is a schematic top view of FIG. 4, and FIG. 4 is the cross-sectional view along the line section II-II in FIG. 5.

FIG. 6 is a schematic cross-sectional view of a power device according to yet another embodiment of the disclosure.

FIG. 7 is a schematic top view of FIG. 6, and FIG. 6 is the cross-sectional view along the line section in FIG. 7.

FIG. 8A is a schematic front view of a pre-molded chip according to still another embodiment of the disclosure.

FIG. 8B is a schematic back view of a pre-molded chip according to the still another embodiment of the disclosure.

### DESCRIPTION OF THE EMBODIMENTS

A description accompanied with drawings is provided in the following to comprehensively explain exemplary embodiments of the disclosure. However, it is noted that the disclosure may still be implemented according to many other different forms and should not be construed as limited to the embodiments described hereinafter. For clarity of the drawings, the sizes and thicknesses of each region, part and layer may not be illustrated according to practical scaling. For ease of understanding, the same elements in the following description will be designated the same reference numerals.

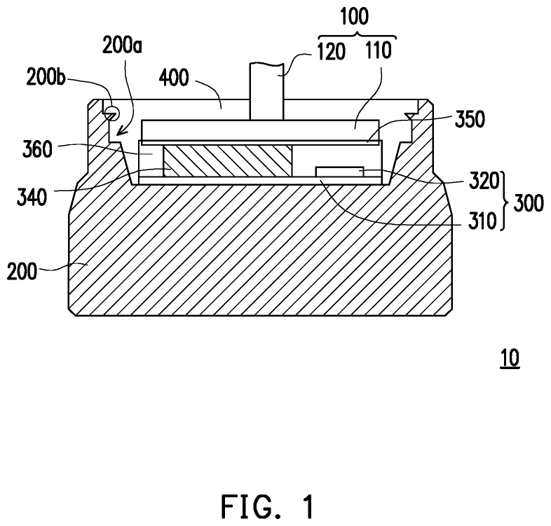

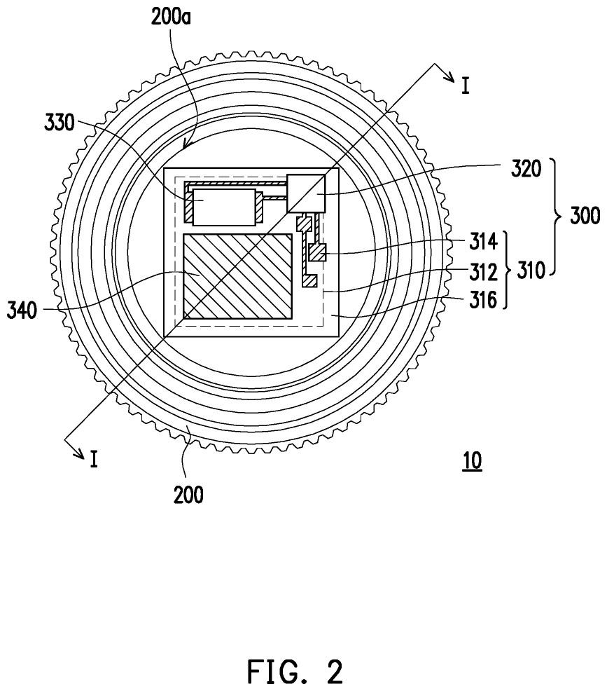

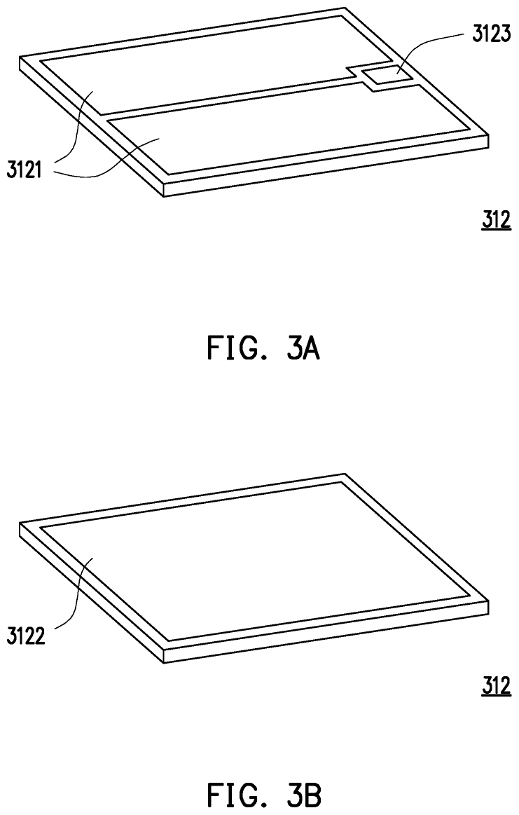

FIG. 1 is a schematic cross-sectional view of a power device according to an embodiment of the disclosure. FIG. 2 is a schematic top view of FIG. 1. For clarity, some elements of the power device are omitted from FIG. 2. FIG. 3A and FIG. 3B are a schematic front and back views of a pre-molded chip according to the embodiment of the disclosure.

Referring to FIG. 1 to FIG. 3B, the power device 10 is, for example, a rectifying diode applied in a vehicle generator for rectifying alternating current into direct current and transmitting direct current to various electrical devices and batteries in the vehicle system. In this embodiment, the power device 10 includes a second terminal 200, a first terminal 100 and a circuit system 300, wherein the second terminal 200 and the first terminal 100 are adapted for connecting to an external circuit, and the circuit system 300 is located between the second terminal 200 and the first terminal 100, and the circuit system 300 is electrically connected to the second terminal 200 and the first terminal 100.

In this embodiment, the circuit system 300 includes a pre-molded chip 310 and a control device 320. As shown in FIG. 2, the detailed structure of the pre-molded chip 310 includes a transistor 312 having a first electrode 3121, a second electrode 3122 and a third electrode 3123 (as shown in FIG. 3A and FIG. 3B) and a first encapsulant 316 adapted for encapsulating the transistor 312. The first terminal 100, the second terminal 200 and the control device 320 are electrically connected to the transistor 312.

For example, the first terminal 100, the second terminal 200 and the control device 320 are respectively electrically connected to the first electrode 3121, the second electrode 3122 and the third electrode 3123 of the transistor 312.

In another embodiment, the pre-molded chip 310 may further include a patterned circuit layer 314 connected to the transistor 312. The patterned circuit layer 314 may be electrically connected to at least one of the first electrode 3121, the second electrode 3122 and the third electrode 3123 of the transistor 312. The first encapsulant 316 encapsulates the patterned circuit layer 314 and a part of the patterned circuit layer 314 is exposed. For example, the patterned circuit layer 314 is electrically connected to the first electrode 3121 and the third electrode 3123, and the first terminal 100 and the control device 320 are respectively electrically connected to the first electrode 3121 and the third electrode 3123 via the exposed part of the patterned circuit layer 314. In this embodiment, the second electrode 3122 is exposed from the pre-molded chip 310 encapsulated by the first encapsulant 316, and the exposed second electrode 3122 is electrically connected to the second terminal 200.

In this embodiment, the transistor 312 is, for example, a field effect transistor controlled by voltage or current. In an embodiment, the transistor 312 is, for example, a MOSFET, an insulated gate bipolar transistor or a gallium nitride transistor. For example, when the transistor 312 is a MOSFET, the source, drain and gate of the MOSFET are the first electrode 3121, the second electrode 3122, and the third electrode 3123 of the transistor 312, respectively. The pads of the gate and the source of the MOSFET are on the same side facing toward the first terminal 100, the pad of the drain is on the other side facing toward the second terminal 200, and the second terminal 200 is electrically connected to the MOSFET via the pad of the drain. Since the MOSFET has a low resistance during turn-on, a lower turn on voltage (for example, a V_{F} less than 0.5V) may be achieved, and the efficiency of the power device 10 is thereby improved. Further, the control device 320 directly contacts the patterned circuit layer 314 and is electrically connected to the third electrode 3123 of the transistor 312 via the patterned circuit layer 314; therefore traditional problems of high resistance and poor reliability caused by wire bonding are eliminated, and the integrity of the circuit system 300 is thereby improved.

In addition, the power device 10 may further include a capacitor 330, a conductive spacer 340 and so on, and a bonding material 350 (such as a solder) may be disposed between the first terminal 100 and the conductive spacer 340 so as to electrically connect the first terminal 100 and the transistor 312 in the pre-molded chip 310. As such, the inflowing alternating current is rectified to a direct current by the circuit system 300 having a rectifying function, and then the direct current is output from the power device 10.

In this embodiment, the second terminal 200 is, for example, a base electrode having a groove 200a, and the shape of the second terminal 200 is, for example, a circle, a square or a hexagon, but the disclosure is not limited thereto. In fact, the second terminal 200 may adopt different shapes or forms according to the product design requirements, for example, not having a groove, or further including a raised base (not illustrated) on the surface for placing the circuit system 300. In this embodiment, a material of the second terminal 200 includes aluminum, copper or an alloy of the foregoing metals (such as an aluminum alloy), preferably copper or aluminum. If the material of the second terminal 200 is aluminum, it may have a good thermal conductivity, a good electric conductivity and a large heat capacity. In addition, as shown in FIG. 2, the outer periphery of the second terminal 200 of this embodiment may be gear-shaped, so that during installing the power device 10 to the vehicle generator by a press-fit connection technology, it is ensured that damages or defects do not occur on the circuit system 300 in the power device 10.

In this embodiment, the first terminal 100 is, for example, an electrode including a base 110 and a lead 120 connected to the base 110. In this embodiment, the base 110 of the first terminal 100 is electrically connected to the lead 120, and the first terminal 100 is connected to the external circuit by the lead 120. As shown in FIG. 1, the base 110 of the first terminal 100 and a part of the lead 120 are located in the groove 200a of the second terminal 200. A surface of the base 110 of the first terminal 100 facing toward the circuit system 300 serves as an interface electrically conductive with the circuit system 300. In this embodiment, an area of the base 110 of the first terminal 100 is substantially smaller than an area of the bottom surface of the groove 200a of the second terminal 200. In this embodiment, the bottom surface of the base 110 of the first terminal 100 is in a square shape close to the shape of the pre-molded chip 310. In some other embodiments, the shape of the base 110 of the first terminal 100 is a circle or a hexagon, but the disclosure is not limited thereto. In this embodiment, a material of the first terminal 100 includes aluminum, copper or an alloy of the foregoing metals, such as a copper alloy, an aluminum alloy, and so on.

Next, a manufacturing process of the power device 10 will be briefly described, but the power device of the disclosure is not limited to the following process.

First, a transistor 312 is provided, and vias (not illustrated) and a patterned circuit layer 314 are formed on the transistor 312. In this embodiment, the vias may be formed on the pads of the source and gate of the transistor 312, and then the patterned circuit layer 314 may be formed on the vias, but the disclosure is not limited thereto. Then, the first encapsulant 316 encapsulates the transistor 312, the vias and the patterned circuit layer 314 by a molding process, for example. At this point, the process of manufacturing the pre-molded chip 310 is generally completed. In addition, the first encapsulant 316 exposes the patterned circuit layer 314 for the subsequent electrical connections. In this embodiment, a material of the first encapsulant 316 may include, for example, an epoxy resin, a silicone resin, a biphenyl resin, an unsaturated polyester or a ceramic material. A material of the vias and patterned circuit layer 314 is, for example, copper or other suitable metal.

Next, a control device 320, a capacitor 330 and a conductive spacer 340 are mounted on the patterned circuit layer 314. The control device 320 is electrically connected to the transistor 312 via the patterned circuit layer 314 so as to provide a drive current to control whether the transistor 312 is turned on or off. The capacitor 330 may be respectively electrically connected to the control device 320 and the transistor 312 via the patterned circuit layer 314. The conductive spacer 340 is located between the pre-molded chip 310 and the first terminal 100 so as to electrically connect the pre-molded chip 310 and the first terminal 100, and the conductive spacer 340 also has an effect of heat dissipation. Next, by method such as the molding process, a second encapsulant 360 is formed between the pre-molded chip 310 and the first terminal 100 so as to package elements such as the pre-molded chip 310, the control device 320, the capacitor 330 and the conductive spacer 340. At this point, the manufacturing of the circuit system 300 is generally completed. In this embodiment, the second encapsulant 360 exposes a part of a surface of the conductive spacer 340 for the subsequent electrical connections. In another embodiment, a layer of a bonding material 350 may be formed between the second encapsulant 360 and the first terminal 100, and the second encapsulant 360 exposes a surface of the bonding material 350 for subsequent electrical connection. In this embodiment, a material of the second encapsulant 360 may include, for example, an epoxy resin, a silicone resin, a biphenyl resin, an unsaturated polyester, or a ceramic material. A material of the bonding material 350 is, for example, lead-tin, tin-silver, or sintered silver solder, but the disclosure is not limited thereto.

Then, the circuit system 300 is disposed on the second terminal 200 such that the second terminal 200 is electrically connected to the transistor 312 in the circuit system 300; that is, an electrode of the transistor 312 is bonded to the second terminal 200, and then the first terminal 100 is disposed on the circuit system 300. Also, the transistor 312 in the circuit system 300 is electrically connected to the first terminal 100 via the exposed part of the conductive spacer 340 or via the bonding material 350. In other embodiments, another bonding material (not illustrated) may be optionally formed on a bottom surface of the groove 200a of the second terminal 200 and electrically connected to the second terminal 200 and the transistor 312 in the circuit system 300 via said bonding material (for example, a solder). In FIG. 1 and FIG. 2, the circuit system 300 and a part of the first terminal 100 are located in the groove 200a of the second terminal 200. As shown in FIG. 1, in order to connect the external circuit, the lead 120 of the first terminal 100 extends from the groove 200a of the second terminal 200 to the outside of the groove 200a. In addition, the base 110 of the first terminal 100 is connected to the bonding material 350. An area of the exposed bonding material 350 may be greater than or equal to an area of the base 110 of the first terminal 100, but the disclosure is not limited thereto. In an embodiment, on the second terminal 200, the groove 200a may be filled with the third encapsulant 400 by a method such as the molding process to cover the conductive spacer 340, the circuit system 300 and part of the first terminal 100. In another embodiment, the third encapsulant 400 may be omitted if the first terminal 100 and the circuit system 300 can be firmly installed on the second terminal 200. In another embodiment, if the second terminal 200 does not have a groove, the third encapsulant 400 is located on the second terminal 200 to cover the circuit system 300 and the part of the first terminal 100. At this point, the process of manufacturing the power device 10 is generally completed. In this embodiment, a material of the third encapsulant 400 may include, for example, an epoxy resin, a silicone resin, a biphenyl resin, an unsaturated polyester or a ceramic material. In an embodiment, a material of the first encapsulant, a material of the second encapsulant and a material of the third encapsulant materials may be the same. In another embodiment, a material of the first encapsulant, a material of the second encapsulant and a material of the third encapsulant materials may be different materials, but the disclosure is not limited thereto.

In addition, in FIG. 1, a wall of the groove 200a is designed as a stepped form and has an inwardly extending continuous ring 200b on a wall near the top of the groove 200a, such that the third encapsulant 400 is controlled at a fixed position and the fatigue life of the power device 10 is thereby improved. However, the disclosure is not limited thereto. The wall of the groove 200a may also be a smooth surface or in other designed forms.

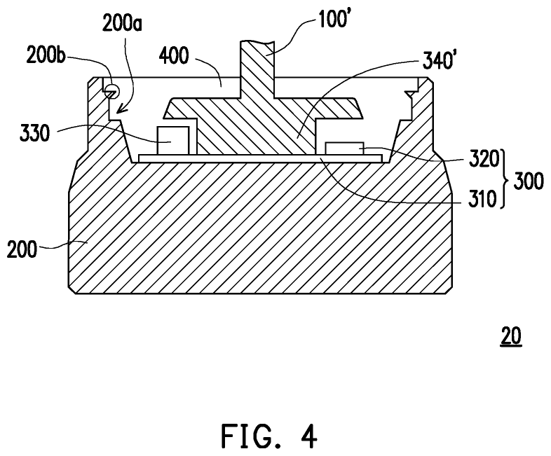

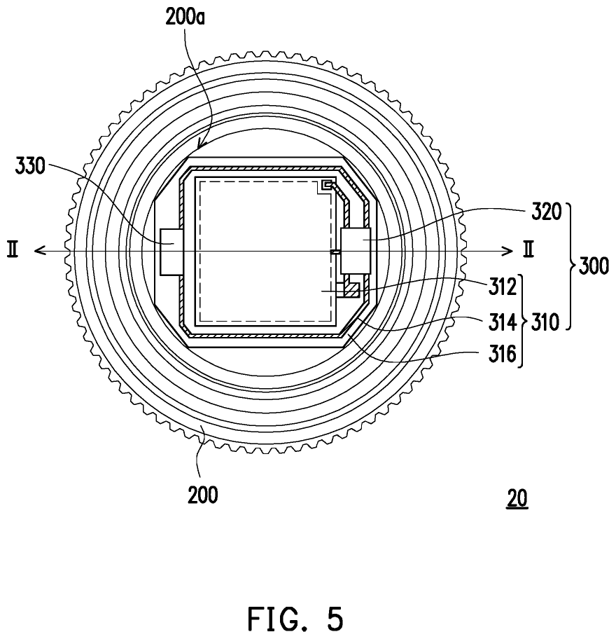

FIG. 4 is a schematic cross-sectional view of a power device according to another embodiment of the disclosure. FIG. 5 is a schematic top view of FIG. 4. For clarity, some elements of the power device are omitted from FIG. 5.

Referring to both FIG. 4 and FIG. 5, a power device 20 is similar to the power device 10 described above, wherein the difference between the two is that a conductive spacer 340′ and a first terminal 100′ are integrally formed. The connection relationships and materials of other elements have been described in detail in the first embodiment and are not to be repeated hereinafter. In this embodiment, with the integrally formed conductive spacer 340′ and first terminal 100′, the second encapsulant 360 in the power device 10, for example, may be omitted, and the third encapsulant 400 may be utilized to cover the pre-molded chip 310, the control device 320, the capacitor 330, the conductive spacer 340′, and a part of the first terminal 100′ so as to further simplify the manufacturing process.

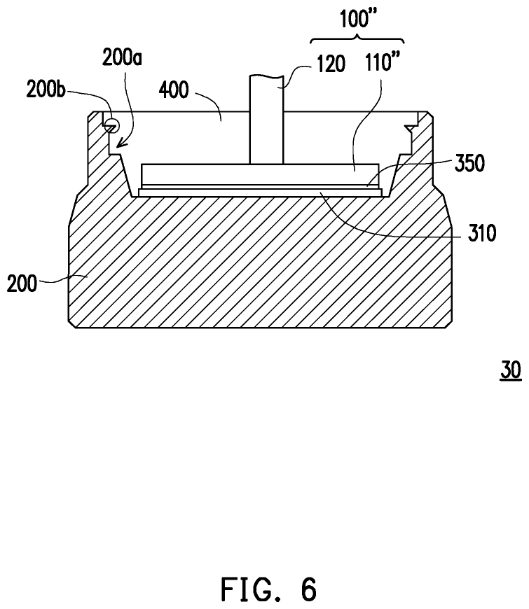

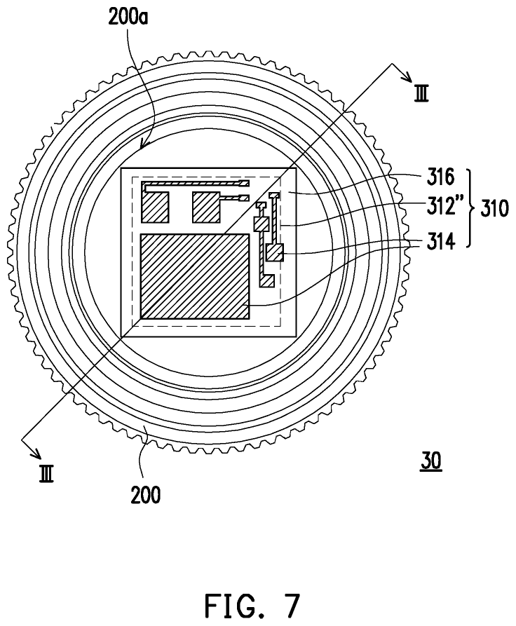

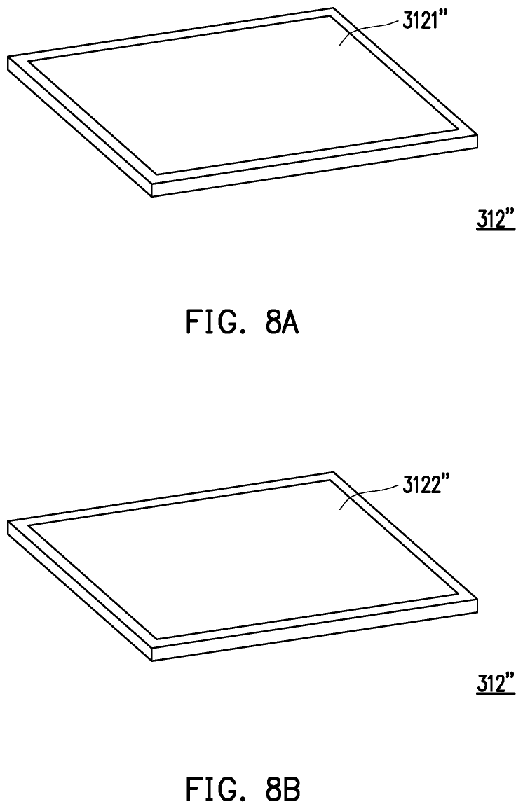

FIG. 6 is a schematic cross-sectional view of a power device according to yet another embodiment of the disclosure. FIG. 7 is a schematic top view of FIG. 6. For clarity, some elements of the power device are omitted from FIG. 7. FIG. 8A and FIG. 8B are schematic front and back views of a pre-molded chip according to still another embodiment of the disclosure.

Referring to FIG. 6 to FIG. 8B, a power device 30 is similar to the power device 10 described above, wherein the difference between the two is that elements such as the control device 320, the capacitor 330 and the conductive spacer 340 are omitted from between the second terminal 200 and a first terminal 100″. The connection relationships and materials of other elements have been described in detail in the first embodiment and are not to be repeated hereinafter.

In this embodiment, a first terminal 100″ and the second terminal 200 are electrically connected to a transistor 312″. For example, the first terminal 100″ and the second terminal 200 are respectively electrically connected to a first electrode 3121″ and a second electrode 3122″ of the transistor 312″. In other words, a base 110″ of the first terminal 100″ substantially contacts the exposed first electrode 3121″ directly or contacts the exposed first electrode 3121″ via the bonding material 350. As such, the power device 30 having a simplified manufacturing process is obtained thereby.

In another embodiment, the pre-molded chip 310 may further include a patterned circuit layer 314 electrically connected to the first electrode 3121″. The first terminal 100″ is electrically connected to the first electrode 3121″ via the patterned circuit layer 314 exposed from the first encapsulant 316. In other words, a base 110″ of the first terminal 100″ substantially contacts the exposed patterned circuit layer 314 directly or contacts the exposed patterned circuit layer 314 via the bonding material 350. As such, the power device 30 having a simplified manufacturing process is obtained thereby.

In the disclosure, the power device 10, the power device 20 and the power device 30 as described above may be applied to a rectifier device of a vehicle generator and thereby improves the efficiency of the same.

In sum of the above, in the power device for rectifier of the disclosure, the circuit system directly connects the control device via a pre-molded chip, such that a circuit system with a low parasitic effect and low conductive resistance may be obtained and the V_{F} of the power device may decrease thereby. As such, it can significantly reduce the power conversion loss, and thus the efficiency of the power device for rectifier can be improved.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A power device for rectifier, comprising:
a first terminal and a second terminal respectively adapted for connecting to an external circuit; and
a circuit system located between the first terminal and the second terminal, and electrically connected to the first terminal and the second terminal, wherein the circuit system comprises a pre-molded chip and a control device, wherein
the pre-molded chip comprises:
a transistor having a first electrode, a second electrode and a third electrode; and
a first encapsulant encapsulating the transistor, wherein
the first terminal, the second terminal and the control device are respectively electrically connected to the first electrode, the second electrode and the third electrode of the transistor.

2. The power device for rectifier according to claim 1, wherein the pre-molded chip further comprises a patterned circuit layer, the patterned circuit layer electrically connected to at least one of the first electrode, the second electrode and the third electrode of the transistor, and the first encapsulant encapsulates the patterned circuit layer and exposes a part of the patterned circuit layer.

3. The power device for rectifier according to claim 2, wherein the patterned circuit layer is electrically connected to the first electrode and the third electrode, and the first terminal and the control device are respectively electrically connected to the first electrode and the third electrode via the exposed part of the patterned circuit layer.

4. The power device for rectifier according to claim 2, wherein the second electrode is exposed from the pre-molded chip encapsulated by the first encapsulant, and the second terminal is electrically connected to the exposed second electrode.

5. The power device for rectifier according to claim 1, wherein a material of the first terminal and a material of the second terminal respectively comprise aluminum, copper or an alloy thereof.

6. The power device for rectifier according to claim 1, wherein the transistor includes a field effect transistor controlled by voltage or current.

7. The power device for rectifier according to claim 1, wherein the transistor includes a metal oxide semiconductor field effect transistor, an insulated gate bipolar transistor or a gallium nitride transistor.

8. The power device for rectifier according to claim 1, wherein a material of the first encapsulant comprises an epoxy resin, a silicone resin, a biphenyl resin, an unsaturated polyester or a ceramic material.

9. The power device for rectifier according to claim 1, wherein the first terminal comprises a base and a lead, and a shape of a bottom surface of the base is a circle, a square or a hexagon, and a shape of the second terminal is a circle, a square or a hexagon.

10. The power device for rectifier according to claim 1, further comprising a conductive spacer, located between the pre-molded chip and the first terminal and electrically connecting the pre-molded chip and the first terminal.

11. The power device for rectifier according to claim 10, wherein the conductive spacer and the first terminal are integrally formed.

12. The power device for rectifier according to claim 11, further comprising a second encapsulant, located on the second terminal and covering the conductive spacer, the circuit system and a part of the first terminal.

13. The power device for rectifier according to claim 10, further comprising a second encapsulant located between the pre-molded chip and the first terminal, encapsulating the control device and the conductive spacer, and exposing a part of the conductive spacer.

14. The power device for rectifier according to claim 13, further comprising a bonding material located between the second encapsulant and the first terminal.

15. The power device for rectifier according to claim 13, further comprising a third encapsulant located on the second terminal and covering the conductive spacer, the circuit system and a part of the first terminal.

16. The power device for rectifier according to claim 15, wherein a material of the second encapsulant and a material of the third encapsulant comprise an epoxy resin, a silicone resin, an unsaturated polyester or a ceramic material.

17. A power device for rectifier, comprising:
a first terminal and a second terminal respectively adapted for connecting to an external circuit; and
a pre-molded chip located between the first terminal and the second terminal, wherein the pre-molded chip comprises:
a transistor having a first electrode and a second electrode; and
a first encapsulant encapsulating the transistor, wherein the first terminal and the second terminal are respectively electrically connected to the first electrode and the second electrode of the transistor.

18. The power device for rectifier according to claim 17, wherein the pre-molded chip further comprises a patterned circuit layer electrically connected to the first electrode, the first encapsulant encapsulates the patterned circuit layer and exposes a part of the patterned circuit layer, and the first terminal is electrically connected to the first electrode via an exposed part of patterned circuit layer.

19. The power device for rectifier according to claim 17, wherein the second electrode is exposed from the pre-molded chip encapsulated by the first encapsulant, and the second terminal is electrically connected to the exposed second electrode.

20. The power device for rectifier according to claim 17, wherein a material of the first terminal and a material of the second terminal comprise aluminum, copper or an alloy thereof.

21. The power device for rectifier according to claim 17, wherein a material of the first encapsulant comprises an epoxy resin, a silicone resin, a biphenyl resin, an unsaturated polyester or a ceramic material.

22. A rectifier device of a vehicle generator, comprising: the power device for rectifier according to claim 1.

23. A rectifier device of a vehicle generator, comprising: the power device for rectifier according to claim 17.
